(19) United States
(12) Patent Application Publication
(10) Pub. No.: US 2006/0045959 A1
(43) Pub. Date: Mar. 2, 2006

(54) Method of manufacturing electron device and organic electroluminescent display and ink for organic amorphous film

(76) Inventors: Akiko Yasukawa, Suginami (JP); Shoichi Uchino, Annaka (JP); Yoshihiro Arai, Mobara (JP); Masahiro Tanaka, Chiba (JP); Masato Ito, Mobara (JP); Tomio Yaguchi, Sagamihara (JP)

Correspondence Address: REED SMITH LLP, Suite 1400, 3110 Fairview Park, Falls Church, VA, 22042, US

(21) Appl. No.: 11/207,838

(22) Filed: Aug. 22, 2005

(30) Foreign Application Priority Data
Aug. 27, 2004 (JP) 2004-249050

(51) Int. Cl. B05D 5/06

(52) U.S. Cl. 427/66; 252/301.16

(57) ABSTRACT

The present invention provides a method which can form a uniform amorphous film using an organic low molecular weight material which is refined by distillation or sublimation. The viscosity of ink is regulated by mixing two kinds of solvents so as to increase a surface tension of the ink and the solubility of the organic material in a drying step whereby an amorphous film made of an organic material is selectively formed in a recessed region defined by a partition wall layer using an ink jet method.

### CROSS-REFERENCE TO RELATED APPLICATIONS

The disclosure of Japanese Patent Application No. 2004-249050 filed on Aug. 27, 2004 including the specification, drawings and abstract is incorporated herein by reference in its entirety.

### BACKGROUND OF THE INVENTION

1. Field of the invention

The present invention relates to a method for forming a constitutional layer of an electron device and a material thereof and, for example, a method for coating a light emitting layer of an organic EL panel, an electrode or a semiconductor layer of a semiconductor such as an organic thin film transistor using an ink jet method, and the ink composition which is preferably used for such coating.

2. Description of the Related Arts

With respect to the a polymer electroluminescence panel (an organic EL display device, hereinafter simply referred to as an organic EL panel or an OLED) or various electron devices which include semiconductor elements such as thin film transistors, the application thereof to a large-sized panel display (so-called a flat panel type display, hereinafter also simply referred to as “panel”) is expected. In the formation of a constitutional layer of an active region or the like of such a panel, the application of an ink jet method (IJ method) has been considered. The ink jet method is a coating method suitable for the formation of a uniform thin film on a minute region. For example, in a full-color organic EL panel, in general, one color pixel (pixel) is constituted of respective sub pixels of three colors consisting of R, G, B. Here, although the organic EL panel may be also referred to as an organic EL element, the organic EL panel is used for expression.

Conventionally, as a manufacturing method of the organic EL panel, there have been known two kinds of methods, that is, (1) the formation of a film made of a low molecular weight material by a vapor deposition method, (2) the formation of a film made of a polymer material by a wet method such as an ink jet method, a screen printing method or the like. However, the application of the vapor deposition method to the manufacture of the organic EL panel having a large-sized screen size eventually increases the large-sizing of a vapor deposition mask and hence, such application is difficult. Further, since it is necessary to use a mask, there exists a drawback that the material utilization efficiency is low. On the other hand, the polymer material has a drawback that the refining of the polymer material is difficult and the polymer material (especially blue) has a short lifetime.

With respect to this type of related art, a large number of literatures can be named. For example, patent literature 1 discloses a manufacturing method of an organic EL element in which ink containing a low molecular weight fluorescent material is applied to a film formed of polyvinyl carbazole (PVK) by a printing method in place, and the PVK is doped with the fluorescent material by heating thus forming a light emitting layer. Here, in the patent literature 1, the composition of ink is not disclosed.

Patent literature 2 to patent literature 5 disclose a technique for manufacturing a full color display panel using a method which performs the patterning of the low molecular weight organic EL material by vapor deposition using a shadow mask (vapor deposition mask). However, it is difficult to apply this method to the manufacture of the large-sized panel in the same manner as the patent literature 1. Further, there exists a limit with respect to the positioning accuracy and a width of opening of the vapor deposition mask whereby a panel display of high definition cannot be manufactured.

Patent literature 6 discloses a fabrication method of an organic electric field light emitting element which is characterized by forming an organic compound layer by printing. However, the detail of the method is not disclosed.

Patent literature 7 discloses a technique in which by forming and arranging an organic EL material whose patterning has been conventionally considered impossible using an ink jet method, an organic light emitting layer possessing light emitting colors of red, green and blue is arbitrarily patterned for every pixel thus realizing an active matrix type organic EL panel capable of performing a full-color display. Further, with respect to the organic EL material, this patent literature 7 discloses polytetrahydrothiophenylphenylene (impossible to sublimate and refine) which constitutes a precursor. After the publication of this patent literature 7, in forming the organic EL element by the ink jet method, the use of the polymer light emitting material becomes general. This is because that the formation of an amorphous thin film from a solution is difficult due to the aggregation and the crystallization of the low molecular weight material.

Patent literature 8 discloses an organic light emitting device such as a highly-functional full-color organic EL display body which can be inexpensively manufactured by uniformly patterning a low molecular weight (monomer) organic light emitting layer with high definition for every pigment using a wet patterning method and a manufacturing method thereof. To be more specific, the patent literature 8 discloses a manufacturing method of an organic light emitting device which forms the organic material layer by the wet patterning method using ink which contains an organic material in a hydrophobic organic solvent having the moisture solubility of 5 wt % or less at a room temperature.

Patent literature 9 discloses the composition for an organic EL element which is used in forming a pattern by an ink jet method and contains a precursor of conjugated polymer organic compound mainly forming a light emitting layer and at least one kind of fluorescent dye for changing the light emitting property of the light emitting layer. Further, the patent literature 9 discloses that the composition includes at least one of conditions that a contact angle to a material forming a nozzle face of an ink jet head is 30 to 170°, the viscosity is 1 to 20 cp and the surface tension is 2 to 70 dyne. Here, the composition is limited to the precurs or of conjugated polymer organic compound (difficult to sublimate or refine).

Further, non-patent literature 1 discloses a technique for forming a film made of TPD which is a low molecular weight hole injection material by screen printing.

Non-patent literature 2 discloses a technique for manufacturing films made of TDAPB which is a low molecular weight hole transport material and a Ga complex which is a low molecular weight light emitting material by spin coating. However, it is difficult to manufacture a full color element in three separate colors by spin coating.

Patent literature 10 discloses that an organic EL element which is fabricated using spiro 6 φ which is a low molecular weight material as a light emitting material by spin coating is not crystallized for a long time. However, it is difficult to manufacture a full color element in three separate colors by spin coating.

Non-patent literature 3 discloses a technique which fabricates a phosphor light emitting element by applying a light emitting material which is prepared by mixing Ir(ppy)3, PBD in TDAPB which constitutes a host material to PEDOT by spin coating. Also in this technique, it is difficult to manufacture a full color element in three separate colors by spin coating in the same manner as the above-mentioned techniques.

Patent literature 11 discloses the ink composition for an organic EL device which contains an organic light emitting material and at least one kind of high-boiling-point solvent which has a boiling point of 200° C. or more. Although not explicitly described in this literature, a main object of the ink composition is a polymer light emitting material.

Patent literature 12 discloses that when a thin film is formed by discharging ink containing the above-mentioned organic material into recessed regions defined by partition wall layers, the aggregation and the crystallization of the organic material are generated and hence, it is impossible to obtain a uniform amorphous film.

[Patent literature 1] Japanese Patent Laid-Open Hei7(1995)-235378

[Patent literature 2] U.S. Patent Specification No. 5294869

[Patent literature 3] Japanese Patent Laid-Open Hei5(1993)-258859

[Patent literature 4] Japanese Patent Laid-Open Hei5(1993)-258860

[Patent literature 5] Japanese Patent Laid-Open Hei5(1993)-275172

[Patent literature 6] Japanese Patent Laid-Open Hei3(1991)-269995

[Patent literature 7] Japanese Patent Laid-Open Hei10(1998)-012377

[Patent literature 8] Japanese Patent Laid-Open 2001-291587

[Patent literature 9] Japanese Patent Laid-Open Hei11(1999)-54270

[Patent literature 10] Japanese Patent Laid-Open Hei7(1995)-278537

[Patent literature 11] Japanese Patent Laid-Open 2003-229256

[Patent literature 12] Japanese Patent Laid-Open 2003-260408

[Non Patent literature 1] IEEE journal on Selected Topics in Quantum Electronics vol. 7, No. 5 (2001) p. 769-773, Ghassan E. Jabbour et al “Screen Printing for the Fabrication of Organic Light-Emitting Device”

[Non Patent literature 2] Adv. Materials, 13, No. 23, December 3, p. 1811-1814, Andreas Elschner et al “Gallium Complexes in Three-Layer Organic Electroluminescent Device”

[Non Patent literature 3] The 51st Lectures held by the Applied Physics Related Coalition, preliminarily published papers, P. 1477, 30a-ZN-10, Yuichi Hino et al, “Study on a phosphor organic EL element using a low molecular weight host material by a wet process”

### SUMMARY OF THE INVENTION

To form a uniform organic-material thin film on a desired region using an ink jet method, (1) it is necessary to ensure the favorable ink discharge property from a nozzle by adjusting the viscosity of ink in an optimum range, (2) it is necessary to suppress the crystallization and the aggregation of an organic material in a drying process of ink droplets, and (3) it is necessary to form the thin film only in the desired region by suppressing pinning of the ink droplets (a phenomenon that a contact area between ink and a substrate is not changed even when a solvent is evaporated).

Although the optimum range of the viscosity of ink differs depending on the ink jet nozzle, the optimum range is generally 1 to 20 mPa.s (described in the patent literature 9) and preferably 5 to 20 mPa.s. However, the viscosity of a solvent which is capable of dissolving the organic material which can be distilled or sublimated and refined and is applicable to the organic light emitting element and the organic semiconductor is 5 mPa.s or less and hence, it is difficult to obtain the ink composition which is applicable to the ink jet method.

Further, in the ink jet method, when the thin film is formed by discharging the ink containing the above-mentioned organic material into the recessed regions defined by the partition wall layers, as also described in the patent literature 12, there arises the drawback that the aggregation and the crystallization of the organic material are generated and hence, the uniform amorphous film cannot be obtained. Further, even when the ink is discharged into the recessed regions defined by the partition wall layers, there arises the so-called pinning that the ink droplets are formed in a state that the ink droplets project from the desired regions and are directly dried as it is and hence, the formation of the uniform thin film becomes further difficult.

Accordingly, it is an object of the present invention to provide a method which can realize the manufacture of an electron device such as a large-sized organic EL panel or an organic thin film transistor using an organic low molecular weight material which can be refined by distillation or sublimation by an ink jet method which exhibits the high material utilization efficiency with a high throughput.

In general, the organic material which is refined by distillation or sublimation exhibits the low solubility to the solvent and exhibits the high aggregation property and hence, the formation of the stable amorphous thin film using such an organic material has been considered difficult. Inventors of the present invention have found out, in the course of studying the manufacture of ink using the organic material which is refined by distillation or sublimation, that it is possible to form the amorphous thin film by controlling the solubility of the organic material and the surface tension of ink in an ink drying step using a mixed solvent formed of two kinds of solvents in the ink. To describe the typical constitutions of the present invention, they are as follows.

A manufacturing method of an electron device according to the present invention which realizes the given functional structure by stacking a plurality of activation layers or by arranging the plurality of activation layers in parallel or by stacking the plurality of activation layers as well as by arranging the plurality of activation layers in parallel, is characterized in that

at least one of the plurality of activation layers constitutes an amorphous thin film which is formed by coating the ink composition containing an organic material which can be refined by distillation or sublimation using an ink jet method.

Here, the activation layer indicates a portion (an organic material layer) where the movement or the interaction of carriers (electrons and holes) is controlled in an electron device which includes field effect transistors or diodes made of an organic semiconductor material, wherein when the electron device is specified as an organic electroluminescence display device, the activation layer indicates an organic material layer relevant to a light emitting function such as a light emitting layer or a hole injection layer which is included in a light emitting portion formed in each one of a plurality of pixels.

When the electron device is a simple-matrix-type organic EL panel, the amorphous thin films are formed by coating the ink composition containing the organic material which can be refined by distillation or sublimation to the inside of recessed regions defined by partition wall layers which are formed on a substrate using a printing method.

When the electron device is an active-matrix-type organic EL panel, the amorphous thin films of organic semiconductors are formed by coating the ink composition containing the organic semiconductor material which can be refined by distillation or sublimation to pixel portions defined by partition wall layers which are formed on a thin-film-transistor mounted substrate using an ink jet method.

When the electron device is a thin film transistor, the amorphous thin films of organic semiconductors are formed by coating the ink composition containing the organic semiconductor which can be refined by distillation or sublimation to portions defined by source electrodes and drain electrodes which are formed on a substrate using an ink jet method.

The amorphous-thin-film-forming ink composition according to the present invention for manufacturing the above-mentioned respective electron devices is constituted of a mixed product formed of two kinds of organic solvents having different solubility, that is, a first solvent having the solubility of 0.5 wt % or more and a second solvent having the solubility of 0.1 wt % or less.

The amorphous-thin-film-forming ink composition according to the present invention for manufacturing the above-mentioned respective electron devices is also characterized in that the ink composition satisfies any one of a condition that a boiling point of the first solvent is higher than a boiling point of the second solvent, a condition that a surface tension of the first solvent is higher than a surface tension of the second solvent, and a condition that the viscosity of the second solvent is higher than the viscosity of the first solvent.

The amorphous-thin-film-forming ink composition according to the present invention for manufacturing the above-mentioned respective electron devices is also characterized in that a boiling point of the mixed product organic solvent formed of two kinds of organic solvents is lower than a sublimation temperature of the ink composition which contains the organic material which is refined by the distillation or the sublimation.

The amorphous-thin-film-forming ink composition according to the present invention for manufacturing the above-mentioned respective electron devices is characterized in that the first solvent is an aromatic compound having a boiling point of 140° C. or more and the aromatic compound is an anisole derivative.

The amorphous-thin-film-forming ink composition according to the present invention for manufacturing the above-mentioned respective electron devices is characterized in that the second solvent is an alcoholic compound having a boiling point of 120° C. or more and a ratio of the second solvent with respect to the first solvent is 60 wt % or less.

Here, it is needless to say that the present invention is not limited to the above-mentioned constitution and the constitutions described in embodiments described later and various modifications are conceivable without departing from the technical concept of the present invention.

According to the present invention, it is possible to perform the formation of the amorphous thin film of an organic material which has been considered impossible conventionally in the inside of the pixels using the ink jet method. Further, when the present invention is applied to the manufacture of the organic EL panel, since the manufacturing method of the present invention adopts the wet process, it is possible to manufacture a large-sized organic EL panel at a low cost compared to a mask vapor deposition method. Further, it is possible to obtain an organic EL panel which exhibits the long lifetime and the high reliability substantially comparable to the lifetime and the reliability of the conventional low molecular weight vapor-deposited organic EL panel.

Further, by applying the present invention to the formation of the constitutional layer formed of the source electrode, the drain electrode, the semiconductor layer or the like of the organic thin film transistor, it is possible to obtain the organic thin film transistor having the favorable operational properties. Further, it is needless to say that the present invention is applicable to various electron devices which require the formation of other similar organic thin film.

As described above, the inventors of the present invention have found out, upon the extensive study on the ink solvent system, that by ensuring the optimum ink viscosity by mixing two kinds of solvents and by increasing the surface tension of the ink in the drying step and the dissolution limit of the above-mentioned organic material, it is possible to selectively form the amorphous films made of organic material only in the recessed regions defined by the partition wall layers by an ink jet method.

The first solvent used in the present invention is the first solvent of the above-mentioned organic material, while the second solvent used in the present invention is the second solvent of the above-mentioned organic material. The first solvent is a solvent which exhibits the solubility of 0.5 wt % or more. Here, a lower limit of the solubility is limited by the concentration of solid content of the organic material to be dissolved in the solution. The concentration of solid content is determined based on three parameters consisting of a required film thickness, a pixel area and a discharging volume of ink from a nozzle of an ink jet device, wherein it is possible to form a thin film having a sufficient film thickness as a light emitting layer of an organic EL element provided that the concentration of 0.5 wt % or more is assured. Accordingly, the solubility of the solution with respect to the organic material is set to 0.5 wt % or more.

Further, the solubility of the second solvent is set to 0.1 wt % or less. It is desirable that a boiling point of the first solvent is set higher than a boiling point of the second solvent. With the use of such an ink solution system, the ratio of the first solvent in the ink is increased along with the progress of drying and hence, it is possible to suppress the generation of the crystallization nuclei and the aggregation whereby the formation of the uniform amorphous thin film can be realized.

Further, since it is possible to suppress the precipitation of the above-mentioned organic material on outer peripheral portions of ink droplets in an initial step of drying, it is also possible to suppress the non-uniformity of the thin film attributed to the pinning. In the present invention, the second solvent is added in expectation of a viscosity increasing effect for stabilizing the discharging property of ink from a nozzle of an ink jet device and becomes unnecessary immediately after the discharging and hence, it is desirable that the second solvent is evaporated prior to the evaporation of the first solvent. Accordingly, it is desirable that the difference between the boiling points of the first solvent and the second solvent is set as large as possible.

When the boiling points of the first solvent and the second solvent are less than 140° C., ink is dried on a surface of a nozzle of an ink jet device and there arises a drawback that the nozzle is clogged. Accordingly, it is desirable to set the boiling points of the first solvent and the second solvent to 140° C. or more. For example, when toluene having a boiling point of 111° C. is used, the nozzle is clogged, while when xylene having a boiling point of 140° C. is used, the nozzle is not clogged.

Further, it is desirable that the surface tension of the first solvent is set larger than the surface tension of the second solvent. By combining these solvents, the second solvent which exhibits the low boiling point and the small surface tension is evaporated firstly and the surface tension of the ink is gradually increased along with the progress of drying and hence, the ink tends to easily fall into the inside of the pixels from banks (also referred to as partition walls, separators or separation layers) and hence, the generation of pinning of ink with respect to the banks can be suppressed.

As an example of the first solvent which is applicable to the present invention, it is possible to name the aromatic compounds. Among the aromatic solvents, the anisole derivatives exhibit large surface tensions and dissolve the organic material refined by distillation or sublimation and hence, these anisole derivatives are preferably used as the first solvent. The aromatic compound and the specific anisole derivatives which are applicable to the present invention are listed hereinafter.

[First Solvent]

[Aroma Compounds]

o-xylene, 1,3,5-trimethylbenzene, 1,2,3-trimethylbenzene, 1,2,4-trimethylbenzene, 1,2,3,4-tetramethylbenzene, 1,2,3,5-tetramethylbenzene, cyclohexylbenzene, 1,2,3,4-tetrahydronaphthalene, 5-isopropyl-m-xylene, 5-t-butyl-m-xylene, 1-methylnaphthalene, n-butylphenyl ether, diethylbenzene, isopropylbenzene, 1,2-diisopropylbenzene, 1,3-diisopropylbenzene, 1,4-diisopropylbenzene, o-isopropyltoluene, p-isopropyltoluene, m-isopropyltoluene, benzoic acid methyl, benzoic acid ethyl, benzoic acid butyl, benzoic acid propyl, chlorotoluene, 1,2-dichlorobenzene, 1,3-dichlorobenzene, 2-chloro-p-xylene, 2,4-dichlorotoluene, 3,4-dichlorotoluene, 1,2,3-trichlorobenzene, 1,2,4-trichlorobenzene, bromobenzene, dibromobenzene, phenyl ether, 2-methylacetophenone, 3-methoxyacetophenone, o-toluic acid ethyl ester, anethole.

[Anisole Derivatives]

anisole, 4-methylanisole, 2-bromoanisole, 2-methylanisole, 2-ethylanisole, 4-ethylanisole, 3,5-dimethylanisole, 3,4-dimethylanisole, 2,3-dimethylanisole, 2,6-dimethylanisole, 1,2-dimethylanisole, 1,2-dimethoxybenzene, 1,3-dimethoxybenzene, 1,4-dimethoxybenzene, 1,2,4-trimethoxybenzene, 2-chloroanisole, 2-butylanisole, 1,4-benzodioxane, 1,2-methylenedioxy benzene, 3,4,5-trimethylanisole, 2,3,6-trimethylanisole, 2,3,4-trimethylanisole, 2,3,5-trimethylanisole, 2,4,6-trimethylanisole.

Further, as an example of the second solvent which is applicable to the present invention, monohydric alcohol compounds or polyhydric alcohol compounds which are mixed with the first solvent can be named. Among these alcohol compounds, it is desirable to use the alcohol compounds which exhibit boiling points of 120° C. or more. This is because when the alcohol compounds which exhibit boiling points of 120° C. or less are used, the viscosities thereof are low and it is difficult to increase the viscosity of ink to 5 mPa.s or more. As the specific alcohol compounds which are applicable to the present invention, the following alcohol compounds can be named.

2-ethyl-1-butanol, 2-ethyl-1-hexanol, 1-octanol, 2-octanol, n-octanol, tetrahydrofurfuryl alcohol, n-hexanol, 2-heptanol, n-heptanol, 2-methyl-1-butanol, 2-methyl-1-pentanol, 2,6-dimethyl-4-heptanol, benzylic alcohol, cyclohexanol, 1,2-butanediol, 1,4-butanediol, 1,3-butanediol, 2,3-butanediol, 2,4-pentanediol, 2-methyl-2,4-pentanediol, 1,2-ethanediol.

It is desirable that the concentration of the second solvent in the ink composition of the present invention falls within a range of less than 60 wt %. This is because when the concentration of the second solvent is 60 wt % or more, the solubility of the organic material becomes insufficient and hence, the formation of the uniform amorphous film is hampered by aggregation or crystallization.

The organic material refined by distillation or sublimation which is used in the present invention differs depending on the electron device to which the organic material is applied. When the organic material is applied to the organic EL panel, it is possible to use the light emitting material listed below.

[Light Emitting Material]

Amine compound, diazafluorene compound, spiro compound, fluorene compound, phenoxazine-based compound, oligofluorenylene compound, phenylanthracene derivative, aromatic amineoligomer group, carbazole derivative such as 4,4-dicarbazole-1,1′-biphenyl(CBP), 1,3,5-tris[4-(diphenylamino)phenyl]benzene (TDAPB), anthracene derivative, metallic complex such as A1 complex (Balq, A1q), Zn complex, Ga complex.

Further, it is possible to use the light emitting material which are manufactured by adding pigments which respectively emit lights of three colors consisting of blue, green and red as dopants.

[Blue Dopant]

Stilbene derivative, anthracene derivative, tetracene derivative, Perilene derivative, distyrylamine derivative, distylylarylene derivative, pyrazoline derivative, dichlopentadiene derivative, iridium (III) bis [(4,6-difluorophenyl)-pyridinate-N,C2]picolinate (Firpic)

[Green Dopant]

Quinacridone derivative, coumarin derivative, indophenol derivative, indigo derivative, fac tris (2-phenylpyridine)iridium (Irppy3).

[Red Dopant]

4-(dicyano-methylene)-2-methyl-6-(p-dimethylaminosty rile)-4-pyran (DCM), 4-(dicyanomethylene)-2-tert-butyl-6-(1,1,7,7-tetramethyl durolidyl-9-enyl)-4H-pyran(DCJTB: durolidyl derivative), nile red, 4-(dicyanomethylene)-2-R6-(1,3,3,7,7-pentamethyl durolidyl-9-enyl)-4H-pyran (DCJPR), Eu complex, Tb complex, rhodamine derivative, pyrrolopyrrole derivative, squarylium derivalive, iridium (III) bis (2-(2′-benzothienyl)pyridinato-N-acetylacetonate (Btp2Iracac), platinum-octaethyl porphyrin complex (PtOEP).

When the dopant is a fluorescent pigment, it is desirable that the concentration of the dopant for the light emitting material falls within the range of 0.1 wt % to 10 wt %, and it is more preferable that the concentration of the dopant for the light emitting material falls within the range of 2 wt % to 5 wt %. On the other hand, when the dopant is a phosphor pigment, it is desirable that the concentration of the dopant for the light emitting material falls within the range of 0.1 wt % to 30 wt %, and it is more preferable that the concentration of the dopant for the light emitting material falls within the range of 2 wt % to 10 wt %.

To further improve the properties of the film obtained by film forming, it is possible to manufacture the composition by mixing polymer compound (compound which cannot be vapor-deposited) which constitutes a binder irrelevant to the light emitting properties. A content of the polymer binder is set to a suitable amount for optimizing the light emitting property.

polymethylmethacrylate, polybutylmethacrylate, polycarbonate, polystyrene, polyvinyl biphenyl, polyvinyl phenanthrene, polyvinyl anthracene, polyvinyl perylene, poly vinyl chloride, polyester, polysulfone, polyphenylene oxide, polybutadiene, hydrocarbon resin, ketone resin, phenoxy resin, polyamide, ethyl cellulose, vinyl acetate, ABS resin, polyurethane, melamine resin, unsaturated polyester, alkyd resin, epoxyresin, silicon resin, polyvinyl butyral, polyvinyl acetal.

[Hole Injection Layer/Transport Layer]

A mixture of polythiophene derivative such as polyethylene dioxythiophene (PEDOT) or the like and polystyrene sulfonic acid (PSS) or the like, a mixture of polyaniline and PSS, a mixture of polyaniline and camphor sulfonic acid, a mixture of polypyrrole and dodecyl benzene sulfonic acid, polyfluorene derivative.

[Electron Transport Layer]

oxadiazole, triazole, imidazole, triazine, metallic complex compounds.

[Cathode]

Mg alloy, Al alloy, Al, Ca, Li, Cs, amorphous silicon hydride.

When Al is used as a material of the cathode, in an interface between Al and the light emitting layer or between Al and an electron transport layer, it is possible to form an insulating buffer layer made of alkaline metal of Cs, Ba, Ca, Sr or the like, alkaline earth metal or LiF, CaF₂, SrF₂, BaF₂, Al₂O₃, MgO in the order of 0.01 to 10 mm in thickness.

[Substrate]

A material of the sustrate is not limited to glass and it is possible to use a plastic film made of polyimide, polysulfone, polyethersulfone, polyethylene terephthalate, polybutylene carbonate, polycarbonate, polyether.

[Anode]

Besides ITO (indium tin oxide), alloys such as indium oxide, tin oxide, indium oxide zinc oxide and the like are preferably used. A thin film made of metal such as gold, platinum, silver magnesium or the like can be also used.

Here, the present invention is effective not only in the manufacture of a bottom-emission-type organic EL display device but also in the manufacture of a top-emission-type organic EL panel.

### BRIEF DESCRIPTION OF THE DRAWINGS

FIG. 1A shows steps for explaining an embodiment 1 of a manufacturing method of an organic EL panel to which the present invention is applied;

FIG. 1B shows steps which follow the steps shown in FIG. 1A for explaining the embodiment 1 of the manufacturing method of the organic EL panel to which the present invention is applied;

FIG. 2 is a cross-sectional view for explaining a structural example of the vicinity of one pixel of the organic EL panel which is manufactured using the manufacturing method of the present invention;

FIG. 3 is a view showing a circuit constitutional example of the organic EL panel to which the present invention is applied;

FIG. 4 shows steps for explaining an example of a manufacturing method of an organic thin film transistor to which the present invention is applied;

FIG. 5 is a view showing a cross-sectional structural example of the organic thin film transistor to which the present invention is applied;

FIG. 6 is a schematic view for explaining a mode in which a conductive layer which constitutes the organic thin film transistor explained in conjunction with FIG. 5 is formed by an ink jet method which uses ink according to the present invention;

FIG. 7 is a molecular structural view for explaining one example of a polymer material which constitutes an electrode material of the organic thin film transistor explained in conjunction with FIG. 5; and

FIG. 8 is a molecular structural view for explaining one example of a polymer material which constitutes an insulation material GI of the organic thin film transistor explained in conjunction with FIG. 5.

### DETAILED DESCRIPTION OF THE INVENTION

Hereinafter, embodiments of the present invention are explained in detail in conjunction with drawings.

### Embodiment 1

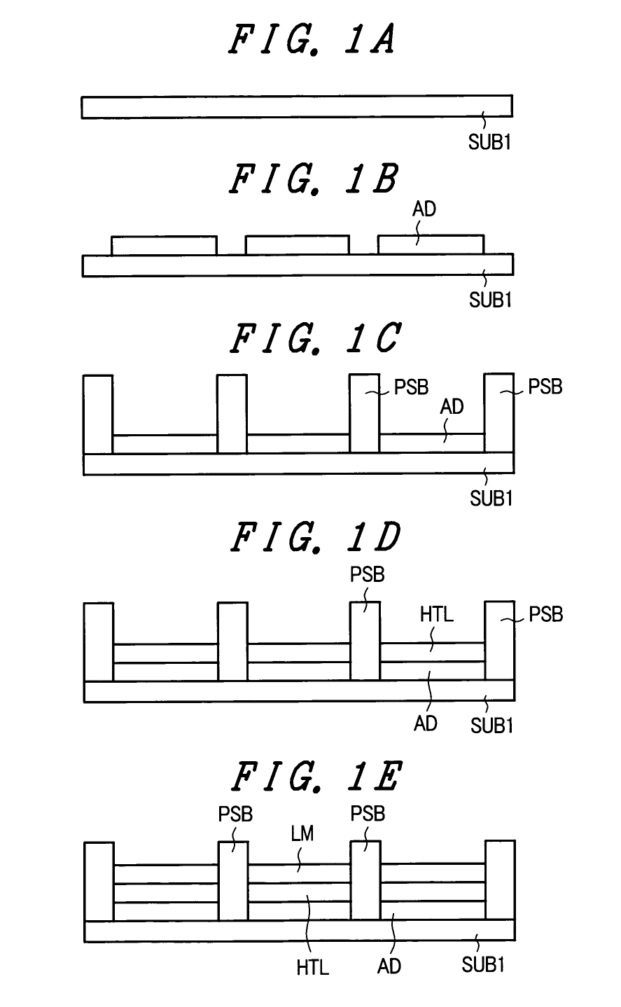

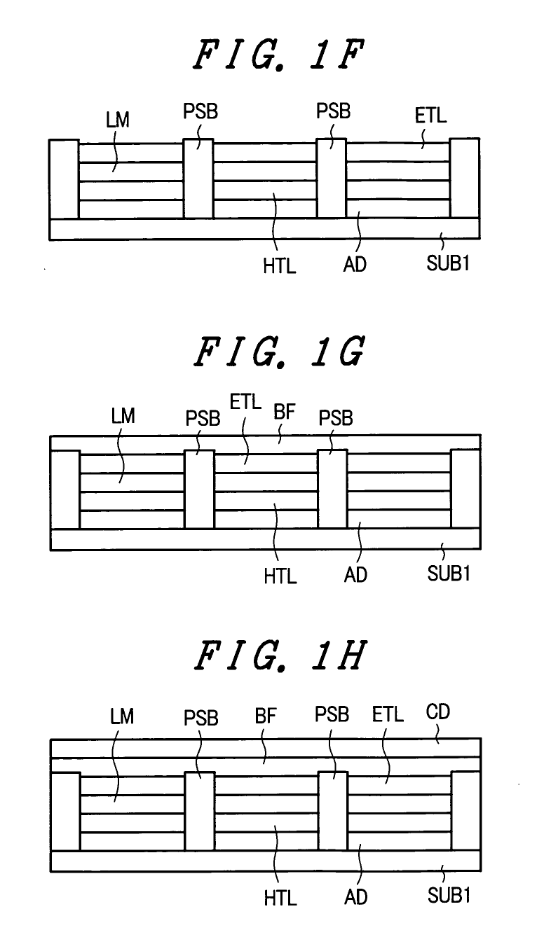

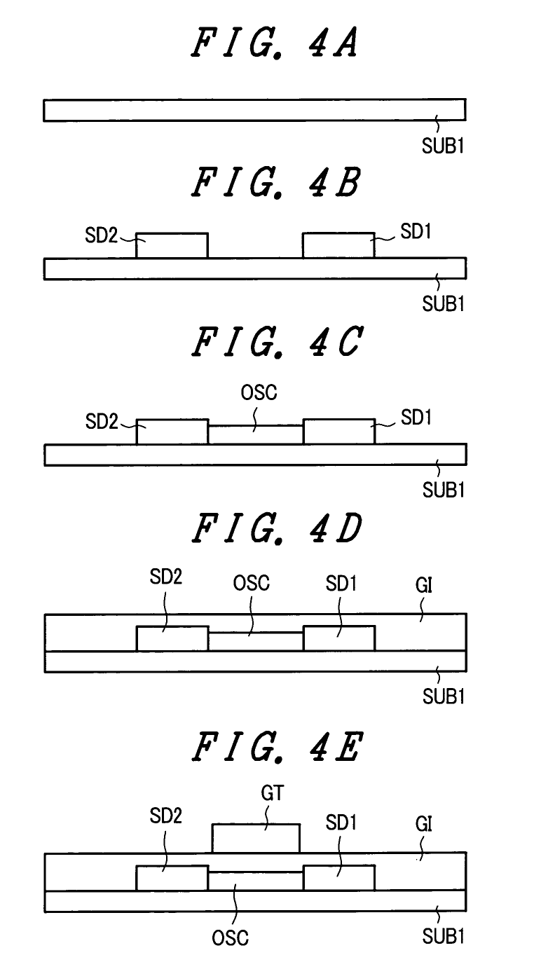

FIG. 1A and FIG. 1B show steps for explaining an embodiment 1 of a manufacturing method of an organic EL panel to which the present invention is applied. Steps advance in order of (a)→(b)→(c)→(d)→(e) in FIG. 1A and, thereafter, (f)→(g)→(h) in FIG. 1B. First of all, an ITO film having a thickness of 150 nm is formed by sputtering on a glass substrate SUB1 having a thickness of 1.1 mm on which thin film transistors are formed. Next, a portion of the ITO which is formed into the film is patterned by an etching treatment using a photolithography method thus forming anodes AD which constitute respective pixel portions. Here, the anodes AD are connected with source electrodes of thin film transistors via contact holes. Thin film transistors formed on the glass substrate SUB1 constitute driving transistors (second switches described later in FIG. 4).

Subsequently, banks PSB having a film thickness of 2 μm which define pixel portions in a state that the banks PSB surround the pixel portions are patterned by a photolithography method which uses acrylic polymer resin. Thereafter, the fluorine plasma treatment is performed to impart the ink repellency to the banks PSB.

A solution which is formed by adding 20 wt % of tert-butanol to a PEDOT/PSS aqueous solution (made by Bayer Co.) is formed into hole injection material ink through a PTFE filter of 0.45 μm. This ink is discharged to the pixel portions of the glass substrate SUB1 using an ink jet printing device thus forming hole injection layers HTL having a thickness of 60 nm and, thereafter, the hole injection layers HTL are baked for 20 minutes at a temperature of 200° C.

Next, 1,3,5-Tris[4-(diphenylamino)phenyl]benzene (also abbreviated as TDAPB), fac-Tris(2-phenylpyridine) iridium(III),(‘fac’indicating isomer of hexacoordinated regular octahedral complex, (also abbreviated as Ir(ppy)₃), and (1,3-bis[(5-p-tert-butylphenyl)-1,3,4-oxadiazol-2-yl]benzene (also abbreviated as OXD-7) are mixed at a weight ratio of 100:80:60. The mixture is dissolved in a 1:1 mixed solvent of 1,2-dimethoxybenzene (boiling point: 206° C., contact angle on Teflon (trade mark): 69°) and cyclohexanol (boiling point: 161° C., surface tension: 32.9 dyne/cm, contact angle on Teflon (trade mark): 58°) such that the concentration of solid content becomes 0.5 wt % thus forming light-emitting material ink through a PTFE filter of 0.2 μm. The viscosity of ink is 5 mPa.s.

The light emitting material ink is discharged to the hole injection layer HTL in the inside of the pixel portion using a piezoelectric ink jet device and, thereafter, the light emitting material ink is baked for 15 minutes using a hot plate of 85° C. after the solvent is evaporated thus obtaining an amorphous light emitting layer LM having a thickness of 50 nm. Thereafter, Alq3 having a thickness of 10 nm is vapor-deposited at a vapor deposition rate of 0.1 nm/second and a vacuum of 10⁻⁶ torr thus forming an electron injection layer ETL. Subsequently, LIF having a thickness of 0.5 nm is vapor-deposited at a vapor deposition rate of 0.01 nm/second thus forming a buffer layer BF. Finally, AL having a thickness of 100 nm is vapor-deposited at a vapor deposition rate of 1 nm/second thus forming a cathode CD.

In the organic EL panel which is obtained in the above-mentioned manner, light is emitted by applying a DC voltage between ITO which constitutes the anode electrode AD of the organic EL panel and Al which constitutes the cathode electrode CD of the organic EL panel in a glove box with the oxygen concentration of 1 ppm or less. It is possible to obtain the green emitted light having the brightness of 1080 cd/m² in a state that the DC voltage of 10V is applied.

Further, although the embodiment 1 describes a case in which the present invention is applied to a so-called active matrix type organic EL panel, the present invention is not limited to such a panel and is also applicable to a single matrix type organic EL display device. That is, on a glass substrate on which a large number of stripe-like anodes are formed, partition wall layers are formed for respective pixel portions, and the ink composition containing an organic material refined by distillation or sublimation is applied to the inside of recessed regions defined by the partition wall layers using an inkjet method thus forming a morphous thin films. Thereafter, using steps similar to the steps described in the embodiment 1, hole injection layers, light emitting layers and electron injecting layers are formed. Further, thereafter, a large number of stripe-like cathodes are formed in a state that the cathodes intersect the anodes.

### COMPARISON EXAMPLE 1

As a comparison example for confirming the advantageous effects of the embodiment 1, an organic EL panel is fabricated in the following manner. That is, an organic EL panel is fabricated in accordance with the exactly same steps as the first embodiment except for that as the solvent of the light emitting material ink in the embodiment 1, dichlorobenzene (boiling point: 180° C., surface tension: 36.6 dyne/cm, contact angle on Teflon: 63°) is used in place of 1,2-dimethoxybenzene, and triacetin(boiling point: 258° C., contact angle on Teflon: 70°) is used in place of cyclohexyl alcohol. In this comparison example, ink does not fall in the inside of the pixel portion and the organic layer adheres to the bank. Further, the aggregation is observed in the thin film in the inside of the pixel portion thus failing to form the uniform amorphous thin film.

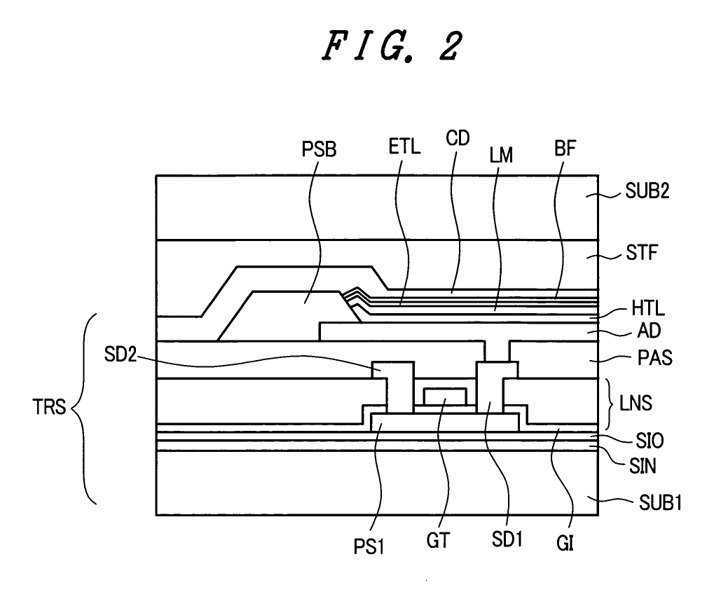

FIG. 2 is a cross-sectional view for explaining a structural example of the vicinity of one pixel of the organic EL panel manufactured in the embodiment 1. In FIG. 2, a substrate TRS provided with thin film transistors (TFT) includes a silicon nitride film SIN and a silicon oxide film SIO on an inner surface of the glass substrate SUB1 as a background layer. On the background layer, a thin film transistor which is constituted of a polysilicon semiconductor layer PSI, a gate electrode GT, a gate insulation film GI, a source electrode SD1, a drain electrode SD2 and an insulation film LNS is formed. An anode AD which is made of ITO is formed above a passivation film PAS as a film, wherein the anode AE is connected with the source electrode SD1 via a contact hole. Here, a portion of the insulation film LNS right below the gate functions as a gate insulation film GI.

Above the anode AD which is formed of ITO, a hole injection layer HTL to which the ink having the above-mentioned composition is applied using a nozzle of an ink jet device is formed. A light emitting layer LM having a specific color is applied to the hole injection layer HTL using an inkjet device. An electron injection layer ETL is formed on the light emitting layer LML as a film and, subsequently, a Ca layer is vapor-deposited to form a cathode buffer layer BF and, further, an aluminum film AL is vapor-deposited to the cathode buffer layer BF to form a cathode CD. Here, further, as an organic layer which is formed between the anode AD and the cathode CD and contributes to the emission of light, there exist layers such as the hole injection layer, the light emitting layer, the electron injection layer and the like which are divided depending on functions or a layer which performs these functions simultaneously.

The substrate TRS provided with the thin film transistors (TFT) having the above-mentioned structure is hermetically sealed with a sealing substrate SUB2. In the example shown in FIG. 2, between the cathodes CD of the substrate TRS provided with the thin film transistors (TFT) and the sealing substrate SUB2, a filling material such as epoxy resin is arranged. However, a dry space may be formed between the substrate TRS and the sealing substrate SUB2. To maintain the dry space, it is desirable to arrange a desiccant at proper positions between both substrates.

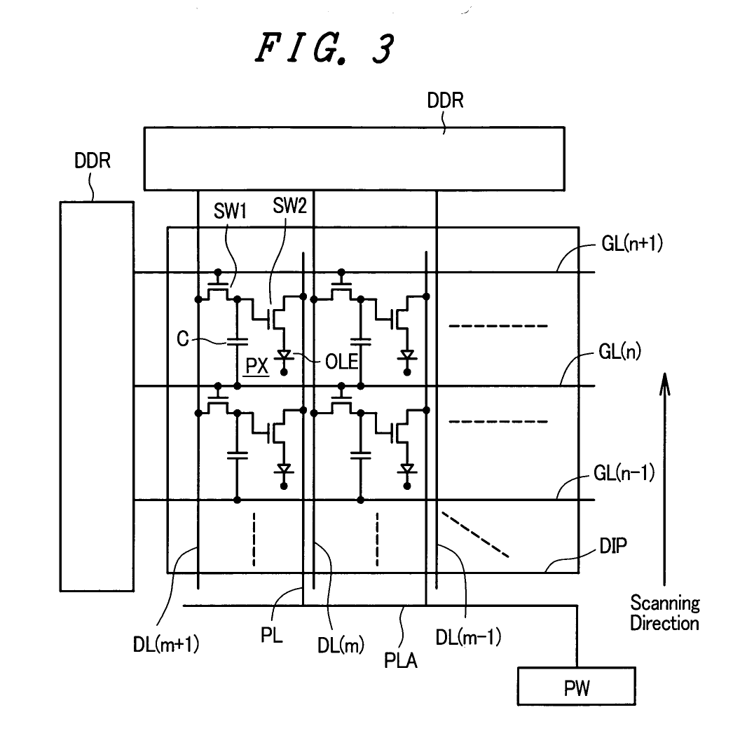

FIG. 3 is a view showing a circuit constitutional example of an organic EL panel to which the present invention is applied. As shown in FIG. 3, on a display region DIP, a plurality of data lines DL (DL (m+1), DL (m), DL (m−1) . . . ) and a plurality of gate lines GL (GL(n+1), GL(n), GL(n−1) . . . ) are arranged in a matrix array. In each one of pixels PX which are surrounded by the respective data lines DL and the respective gate lines GL, a thin film transistor SW1 which constitutes a switching element (control•transistor), a thin film transistor SW2 which constitutes a current supply transistor (drive transistor), a capacitor C for holding data and an organic EL element OLE are arranged.

The control electrode (gate) of the thin film transistor element SW1 is connected to the gate line GL, while one end (drain) of the channel of the thin film transistor element SW1 is connected to the data line DL. The gate of the thin film transistor SW2 is connected to another end (source) of the channel of the thin film transistor SW1, while one electrode (+pole) of the capacitor C is connected to this node. One end (drain) of the channel of the thin film transistor SW2 is connected to the current supply line PL, while another end (source) of the thin film transistor SW2 is connected to the anode of the organic EL element OLE. The data lines DL are driven by a data drive circuit DDR, while scanning lines (gate lines) GL are driven by a scanning drive circuit DDG. Further, the current supply line PL is connected to a current supply circuit PW through a common potential supply bus line PLA.

In FIG. 3, when one pixel PX is selected in response to a signal from the scanning line GL, and the thin film transistor SW1 is turned on, the image data supplied from the data line DL is stored in the capacitor C. Thereafter, at a point of time that the thin film transistor SW1 is turned off, the thin film transistor SW2 is turned on and an electric current flows into the organic EL element OLE from the current supply line PL for an approximately 1 frame period. The electric current which flows in the organic EL element OLE is regulated by the thin film transistor SW2, while a voltage corresponding to a charge stored in the capacitor C is applied to the gate of the thin film transistor SW2. By controlling the thin film transistor SW2 for every pixel, it is possible to control the emission of light of the plurality of pixels and hence, a two-dimensional image is reproduced on a display region DIP.

### Embodiment 2

FIG. 4 shows steps for explaining an embodiment of a manufacturing method of an organic thin film transistor to which the present invention is applied. First of all, to a polyimide substrate SUB1 having a thickness of 150 μm, Au having a thickness of 20 nm is vapor-deposited at a vapor deposition rate 0.1 nm/second under a vacuum of 10⁻⁶ torr. The vapor-deposited Au is patterned using a photolithography method thus forming source electrodes SD1 and drain electrodes SD2. A length of a channel between the source electrode SD1 and the drain electrode SD2 is set to 10 μm.

Next, 1,3,5-Tris[4-(diphenylamino)phenyl]-benzene (TDAPB, produced by Bayer Co.) is dissolved in a 1:1 mixed solvent of 1,2-dimethoxybenzene and cyclohexanol such that the concentration of solid content becomes 0.5 wt % thus forming organic-semiconductor-layer-forming ink through a PTFE filter of 0.2 μm. The ink is discharged using a nozzle of a piezoelectric ink jet device to form a film having a thickness of 50 nm onto the hole injection layer in the inside of the pixel portion. Then, the film is baked for 15 minutes using a hot plate of 85° C. thus obtaining an amorphous semiconductor film OSC.

On a main surface of the polyimide substrate SUB1 on which the source electrodes SD1, the drain electrodes SD2 and the semiconductor films OSC are formed in the above-mentioned manner, an isopropanol solution containing polyvinyl phenol (molecular weight: 20000) is applied by spin coating thus forming a gate insulation film GI made of polyvinyl phenol. Here, although the gate insulation film GI is formed using the organic material such as polyvinyl phenol, the gate insulation film GI may be formed of a silicon oxide film using TEOS (tetraethoxysilane).

Thereafter, by screen printing which uses a silver (Ag) paste, a gate electrode GT having a width of 20 μm is formed on an upper surface of the gate insulation film GI at “a portion which covers the semiconductor film OSC and is spaced apart from the source electrode SD1 and the drain electrode SD2 thus forming an organic thin film transistor (field effect transistor) which uses the semiconductor film OSC made of 1,3,5-Tris[4-(diphenylamine)phenyl]benzene (TDAPB) as a channel. The semiconductor film OSC functions as a so-called activation layer which controls a quantity of carrier (electrons or holes) which flows between the source electrode SD1 and the drain electrode SD2 through the semiconductor film OSC in response to an electric field applied to the semiconductor film OSC from the gate electrode GT through the gate insulation film GI. When the carrier mobility of the organic thin film transistor (the channel formed of the semiconductor film OSC) is measured, the carrier mobility is 1×10⁻⁵cm²/Vs.

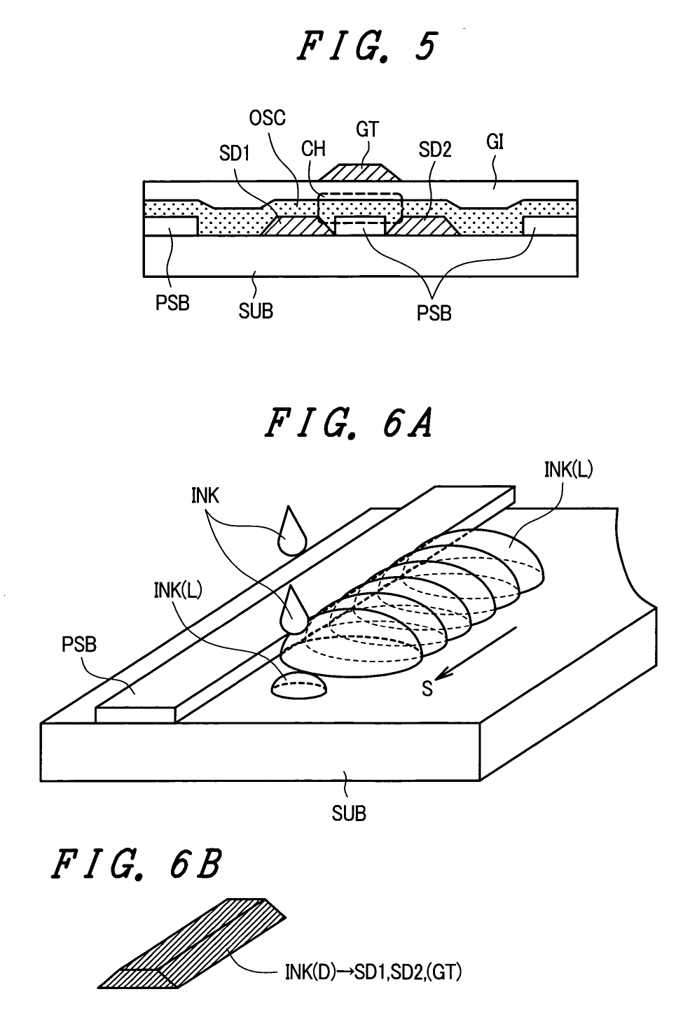

In the above-mentioned manufacturing method of the organic thin film transistor which has been described in conjunction with FIG. 4, the semiconductor film OSC which constitutes the activation layer (channel) is formed by the ink jet method. However, the source electrode SD1, the drain electrode SD2 and the gate electrode GT of the organic thin film transistor can be formed by an ink jet method which uses ink containing a conductive organic material. In pages 1452 to 1455 of No. 12, the volume 70 of “Applied Physics” published by Japan Society of Applied Physics, a technique which forms an electrode of an organic thin film transistor having the cross-sectional structure shown in FIG. 5 by an ink jet method is disclosed. By applying this technique to the manufacturing method of the organic thin film transistor of the above-mentioned embodiment, it is possible to fabricate an electron device in which all parts such as the substrates, insulation layers, semiconductor layers, electrode layers, wiring and the like are formed using organic materials (organic resins).

Hereinafter, the explanation is made with respect to an example in which the organic thin film transistor shown in FIG. 5 is formed on a main surface of the substrate SUB formed of the glass substrate. Members other than the substrate SUB in the organic thin film transistor are formed of organic materials. First of all, by patterning a film formed of an acrylic positive resist (made by JSR Company Ltd.) which is applied to a main surface (one main surface) of the glass substrate SUB using a photolithography method, separators (also referred to as separation layers or partition walls, a function of the separators being explained later) PSB formed of acrylic resin are formed.

Next, by applying the heat treatment to the separators PSB, insolubility to the solvent of the ink described later is imparted to the acrylic resin layer which constitutes the separators PSB. The separators PSB to which the heat treatment is applied is made to be solvent-repellant in the ink with respect to the solvent of the above-mentioned ink using the CF₄ plasma treatment. Thereafter, the ink which is prepared as an aqueous solution containing 25 wt % of tert-butanol in which PEDOT/PSS is dispersed is discharged to both sides of the separators PSB made of acrylic resin on the main surface of the above-mentioned substrate SUB from a nozzle of an ink jet device, a pair of ink droplet patterns are formed on both sides of the separator PSB in a state that the droplet patterns extend along the separator PSP. By drying the pair of ink droplet patterns, by heating the main surface of the substrate SUB, the source electrodes SD1 and the drain electrodes SD2 made of PEDOT/PSS are formed on both sides of the separator PSB. When the source electrodes SD1 and the drain electrodes SD2 are formed using the (so-called low molecular weight material) conductive organic material which is refined by distillation or sublimation in place of the PEDOT/PSS, the conductive organic material may be contained in the above-mentioned ink according to the present invention. Accordingly, the source electrodes SD1 and the drain electrodes SD2 which are made of the conductive organic material are formed by molding in the same manner as the source electrode and the drain electrode which are obtained by the vapor deposition of a metal material such as Au or the like.

Between the source electrode SD1 and the drain electrode SD2, the ink according to the present invention containing 1,3,5-Tris[4-(diphenylamine)phenyl]benzene which is the (so-called low molecular weight) organic semiconductor material which is refined by distillation or sublimation is dropped as mentioned above thus forming an organic semiconductor layer (semiconductor film) OSC which strides over the separator PSB. Further, as shown in FIG. 5, the organic semiconductor layer OSC may be formed by applying the so-called high molecular fluorene-based polymer (molecular weight: 300000), for example, a xylene solution containing fluorene-bithiophene by spin coating. In the latter case, by applying the heat treatment to the main surface of the substrate SUB to which the xylene solution is applied in the nitrogen atmosphere at a temperature of 200° C., the organic semiconductor layer OSC is formed. Accordingly, when the above-mentioned source electrode SD1 and drain electrode SD2 in the organic thin film transistor are formed using the so-called low molecular weight conductive organic material and the semiconductor film OSC which. constitutes the activation layer thereof is formed using the so-called polymer organic semiconductor material, the technique according to the present invention is applied to the formation of the electrodes of the organic thin film transistors.

On the organic semiconductor layer OSC shown in FIG. 5, the gate insulation film GI made of an organic material such as polyvinyl phenol or the like is formed as explained in conjunction with FIG. 4. The plasma treatment CF₄ is applied to an upper surface of the gate insulation film GI, so as to make the upper surface repellant against the solvent of the ink used in the formation of the gate electrode GT by an ink jet method which is performed subsequently. To a region of the upper surface of the gate insulation film GI to which the CF₄ plasma treatment is applied which faces “a portion (so-called channel) which is sandwiched between the source electrode SD1 and the drain electrode SD2 of the semiconductor film OSC”, laser beams are irradiated using a KrF excimer laser and hence, the repellency against the solvent which is imparted to the region is eliminated. In the organic thin film transistor shown in FIG. 5, the “region” on the upper surface of the gate insulation film GI is inevitably positioned above the separator PSB and hence, the laser beams are irradiated from the KrF excimer laser to the upper surface of the gate insulation film GI while targeting the region.

The gate electrode GT is formed as a thin film made of PEDOT/PSS which is obtained by discharging the above-mentioned ink used in the formation of the source electrode SD1 and the drain electrode SD2 to the “region” on the upper surface of the gate insulation film GI to which the laser beams are irradiated from the KrF excimer laser using an ink jet device and by drying the ink droplets adhered to the region by heating. Here, on an upper surface of the gate insulation film GI on which the gate electrode GT is formed, a protective film made of an organic material (not shown in FIG. 5) is formed. The carrier mobility and the like are estimated with respect to the organic thin film transistor shown in FIG. 5 which is fabricated in the above-mentioned manner. From the result of the estimation, the organic thin film transistor shown in FIG. 5 exhibits the favorable properties in the same manner as the organic thin film transistor explained in conjunction with FIG. 4.

In the above-mentioned embodiment, the formation of the source electrode, the drain electrode and the gate electrode which constitute the conductive layers of the thin film transistor and are common with respect to a point that these conductive layers require the patterning is performed using an ink jet method, while the formation of the semiconductor layer and the insulation layer is performed using spin coating. Here, in performing the formation of the source electrode and the drain electrode using the separator PSB which is the pattern made of acrylic resin as a guide and the formation of the gate electrode using the portion of the upper surface of the insulation layer which suppresses the ink repellency, the ink having the above-mentioned composition of the present invention is used.

FIG. 6 is a schematic view for explaining a mode in which the conductive layer which constitutes the organic thin film transistor explained in conjunction with FIG. 5 is formed by the ink jet method using the ink of the present invention. In FIG. 6, the ink of the electrode material which has the composition of the present invention is discharged from the nozzle of the ink jet device along the electrode forming portion where the separator PSB of the glass substrate SUB is arranged. In FIG. 6A, the ink droplets made of the discharged ink and the ink which is dropped on the glass substrate SUB and is still in a liquid form are indicated by INK(L). The ink is discharged while allowing the nozzle to scan in the direction indicated by an arrow S. The discharged ink INK(L) is prevented from being undesirably spread on the glass substrate SUB attributed to the separator PSB, and the liquid droplets are continuously coated in the scanning direction of the nozzle in a state that the droplets are coupled to each other. Thereafter, by heating and drying the ink INK(L), the ink INK(L) is solidified thus forming the strip-like electrode (source electrode SD1, drain electrode SD2 or the gate electrode GT) as shown in FIG. 6B. Here, the solidified ink is indicated by INK(D).

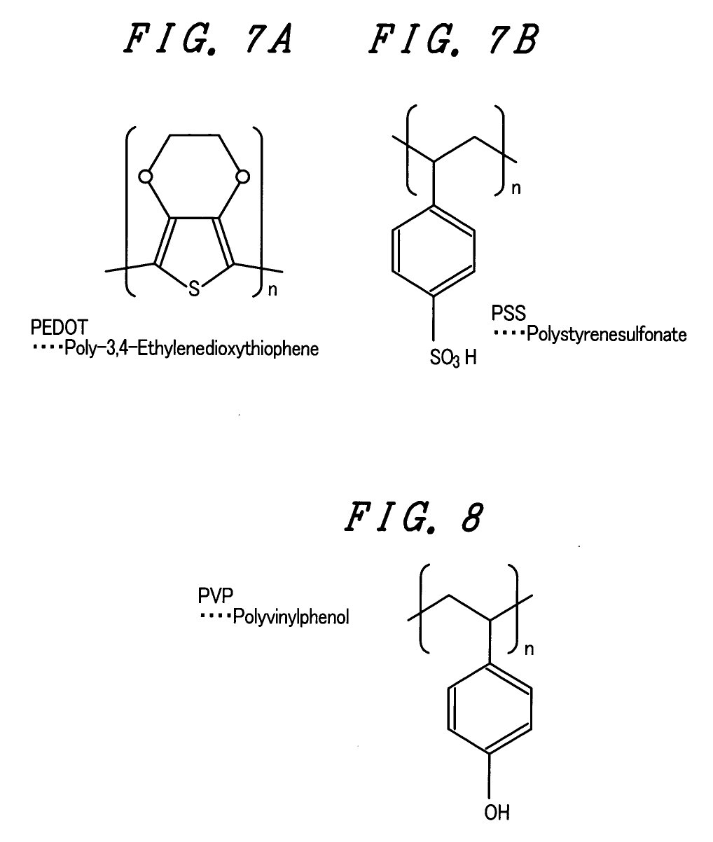

FIG. 7A and FIG. 7B are molecular structural views of one example of the polymer materials which constitute the electrode materials of the organic thin film transistor TFT explained in conjunction with FIG. 5. The electrode materials used in the the organic thin film transistor TFT explained in conjunction with FIG. 5 are above-mentioned PEDOT and PSS, wherein the molecular structure of PEDOT is shown in FIG. 7A and the molecular structure of PSS is shown in FIG. 7B.

FIG. 8 is a molecular structural view of one example of the polymer material which constitutes the insulation material GI of the organic thin film transistor TFT explained in conjunction with FIG. 5. The insulation material GI is a so-called gate insulation layer and is polyvinyl phenol.

What is claimed is:

1. A manufacturing method of an electron device including an amorphous organic material layer, wherein
the organic material layer is formed by applying an ink composition containing an organic material which is refined by distillation or sublimation using an ink jet method.

2. A manufacturing method of an organic EL display device including an amorphous organic material layer in a recessed region which is defined by a partition wall, the manufacturing method comprising the steps of:
forming the partition wall provided with the recessed region; and
applying an ink composition containing an organic material which is refined by distillation or sublimation to the recessed region using an ink jet method.

3. A manufacturing method of a display device in which an organic thin film transistor which is connected with a drain electrode and a source electrode is arranged on a substrate, wherein
a manufacturing process of the organic thin film transistor includes a process which applies an ink composition containing an organic material which is refined by distillation or sublimation between the drain electrode and the source electrode.

4. An amorphous thin film forming ink being constituted of a mixed product which is formed of two kinds of organic solvents which differ in solubility in a state that a first solvent has the solubility of 0.5 wt % or more and a second solvent has the solubility of 0.1 wt % or less.

5. An amorphous thin film forming ink according to claim 4, wherein a boiling point of the first solvent is higher than a boiling point of the second solvent.

6. An amorphous thin film forming ink according to claim 4, wherein a surface tension of the first solvent is higher than a surface tension of the second solvent.

7. An amorphous thin film forming ink according to claim 4, wherein the viscosity of the second solvent is higher than the viscosity of the first solvent.

8. An amorphous thin film forming ink according to claim 4, wherein a boiling point of the mixed product formed of two kinds of organic solvents is lower than a sublimation temperature of the ink composition which contains the organic material which is refined by distillation or sublimation.

9. An amorphous thin film forming ink according to claim 4, wherein the first solvent is an aromatic compound having a boiling point of 140° C. or more.

10. An amorphous thin film forming ink according to claim 9, wherein the aromatic compound is an anisole derivative.

11. An amorphous thin film forming ink according to claim 4, wherein the second solvent is an alcoholic compound having a boiling point of 120° C. or more.

12. An amorphous thin film forming ink according to claim 4, wherein a ratio of the second solvent with respect to the first solvent is 60 wt % or less.
